(19) United States
(12) Patent Application Publication
(10) Pub. No.: US 2025/0366112 A1
(43) Pub. Date: Nov. 27, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Yu-Chang LIN, Hsinchu (TW); Sih-Jie LIU, Hsinchu (TW); Chun-Hung WU, New Taipei (TW); Liang-Yin CHEN, Hsinchu (TW); Chi On CHUI, Hsinchu (TW)

(21) Appl. No.: 19/295,584

(22) Filed: Aug. 9, 2025

Related U.S. Application Data
(63) Continuation of application No. 18/426,664, filed on Jan. 30, 2024.
(60) Provisional application No. 63/600,058, filed on Nov. 17, 2023.

(51) Int. Cl. H10D 62/13; H01L 21/02; H10D 30/01; H10D 30/43; H10D 30/67; H10D 62/10

(52) U.S. Cl. CPC H10D 62/151; H01L 21/02532; H01L 21/02576; H01L 21/02667; H10D 30/014; H10D 30/43; H10D 30/6735; H10D 62/121

(57) ABSTRACT

A semiconductor device structure and methods of forming the same are described. The method includes forming a fin structure from a substrate, depositing a first semiconductor material on a first semiconductor layer of the fin structure, depositing a second semiconductor material on the first semiconductor material, depositing an interlayer dielectric layer over the second semiconductor material, forming an opening in the interlayer dielectric layer to expose the second semiconductor material, performing a first implantation process to form an amorphous region in the second semiconductor material and to implant a first species in the amorphous region, and performing a second implantation process to implant a second species in the amorphous region. The second species includes fluorine, nitrogen, or carbon. The method further includes performing an annealing process to recrystallize the amorphous region.

### CROSS-REFERENCE TO RELATED APPLICATIONS

This application is a continuation application of U.S. patent application Ser. No. 18/426,664, filed Jan. 30, 2024, which claims priority to U.S. Provisional Application Ser. No. 63/600,058, filed Nov. 17, 2023, both of which are incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure, in accordance with some embodiments.

FIGS. 6-20 are cross-sectional side views of various stages of manufacturing the semiconductor device structure taken along line A-A of FIG. 5, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, maybe used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments to be described below relate generally to implanting a species into a source/drain region to retard diffusion of another species from the source/drain region into a channel region. The diffusion of the species from the source/drain region to the channel region may induce Ge out-diffusion from an adjacent semiconductor layer into the channel region, which may negatively impact yield performance.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

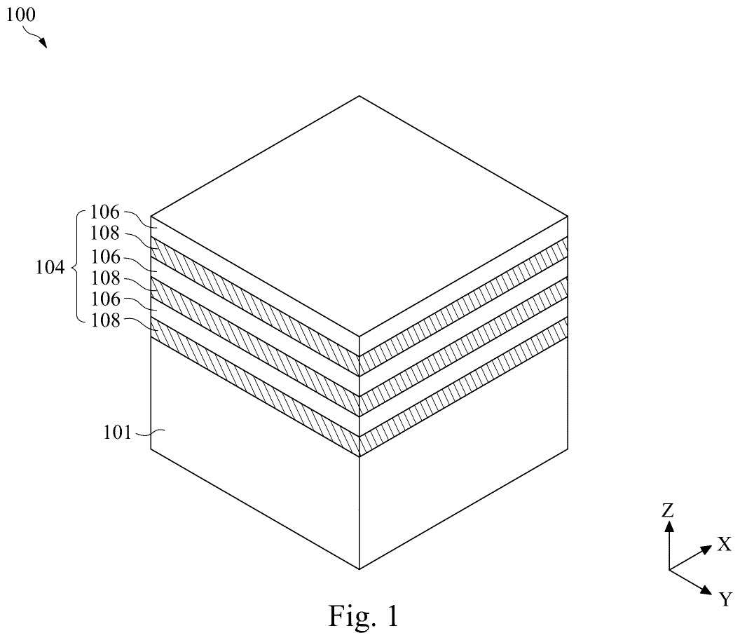

FIGS. 1-20 show exemplary processes for manufacturing a semiconductor device structure 100 according to embodiments of the present disclosure. It is understood that additional operations can be provided before, during, and after processes shown by FIGS. 1-20, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GaAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

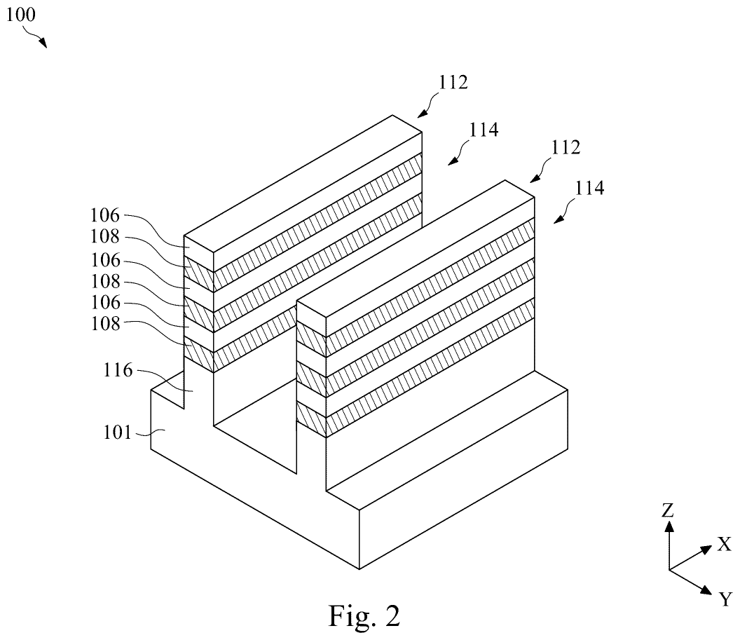

As shown in FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

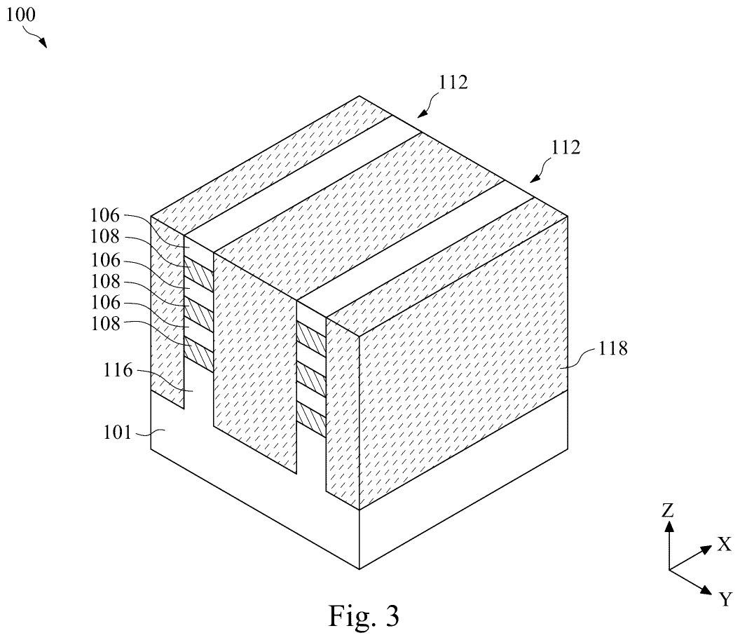

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

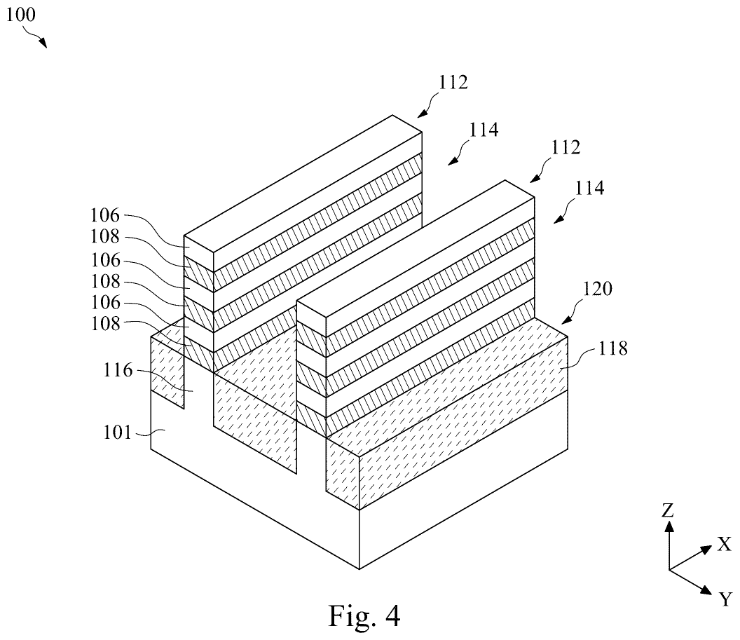

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101. In some embodiments, the isolation regions 120 are the shallow trench isolation (STI) regions.

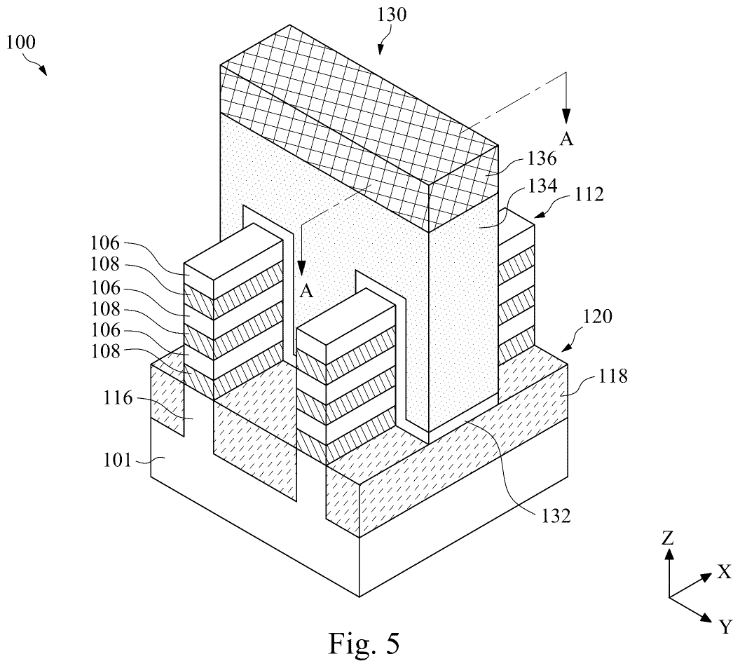

As shown in FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The portions of the fin structures 112 that are covered by the sacrificial gate electrode layer 134 of the sacrificial gate structure 130 serve as channel regions for the semiconductor device structure 100.

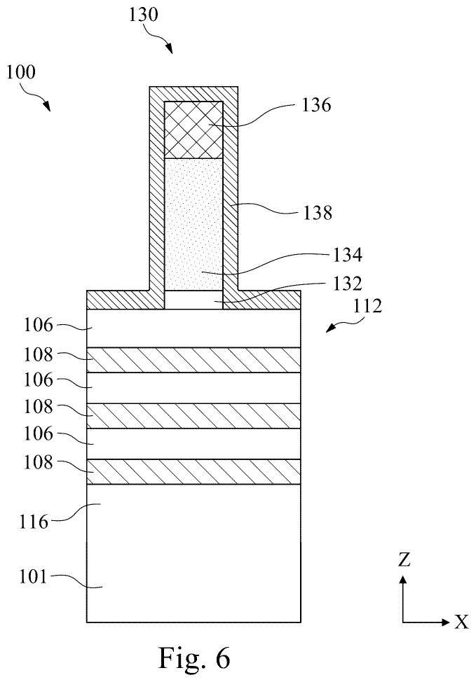

FIGS. 6-20 are cross-sectional side views of various stages of manufacturing the semiconductor device structure 100 taken along line A-A of FIG. 5, in accordance with some embodiments. As shown in FIG. 6, a first gate spacer 138 is deposited on the exposed surfaces of the semiconductor device structure 100. For example, the first gate spacer 138 is deposited on the fin structures 112, the isolation regions 120, and the sacrificial gate structure 130. The first gate spacer 138 may be made of a dielectric material such as silicon oxide, silicon nitride, silicon carbide, silicon oxynitride, SiCN, silicon oxycarbide, SiCON, and/or combinations thereof. The first gate spacer 138 may be formed by any suitable process. In some embodiments, the first gate spacer 138 is a conformal layer formed by a conformal process, such as an atomic layer deposition (ALD) process.

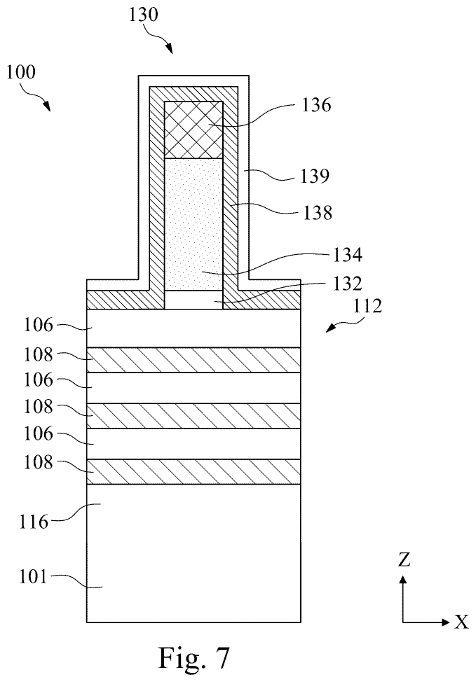

As shown in FIG. 7, a second gate spacer 139 is deposited on the first gate spacer 138. The second gate spacer 139 may include any suitable dielectric material, such as SiOₓ, SiON, SiN, SiCON, or SiCO. The second gate spacer 139 may have a thickness ranging from about 0.5 nm to about 5 nm. The second gate spacer 139 may be formed by any suitable process. In some embodiments, the second gate spacer 139 is deposited by CVD, PECVD, or electron cyclotron resonance CVD (ECR-CVD).

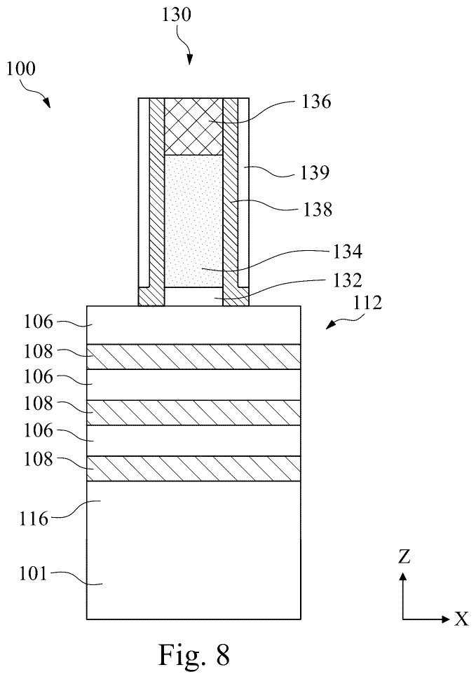

As shown in FIG. 8, horizontal portions of the first and second gate spacers 138, 139 are removed. In some embodiments, the horizontal portions of the first and second gate spacers 138, 139 are removed by an anisotropic etch process. The anisotropic etch process may be a selective etch process that does not substantially affect the mask layer 136, the stack of semiconductor layers 104, and the isolation regions 120.

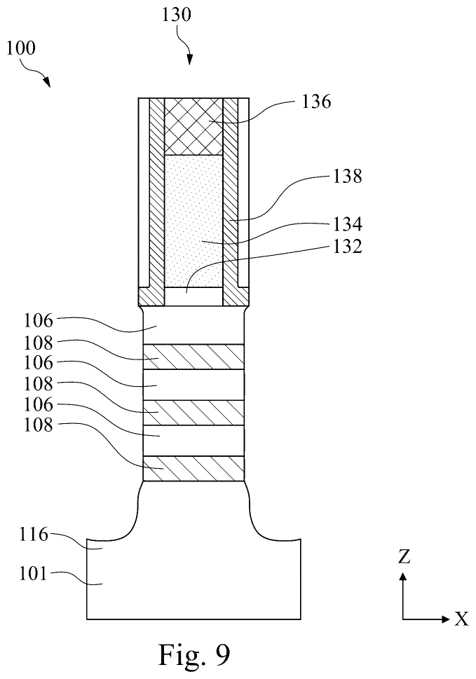

As shown in FIG. 9, the portions of the fin structures 112 not covered by the sacrificial gate structure 130 and the first and second gate spacers 138, 139 are recessed to a level above, at, or below the top surfaces of the isolation regions 120. The recess of the portions of the fin structures 112 can be done by an etch process. The etch process may be a dry etch, such as a RIE, NBE, or the like, or a wet etch, such as using tetramethyalammonium hydroxide (TMAH), ammonium hydroxide (NH₄OH), or any suitable etchant. The well portions 116 are exposed on opposite sides of the sacrificial gate structure 130, as shown in FIG. 9.

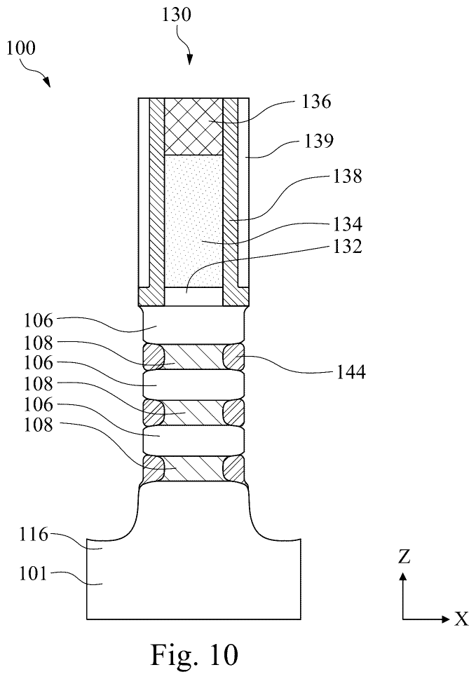

As shown in FIG. 10, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

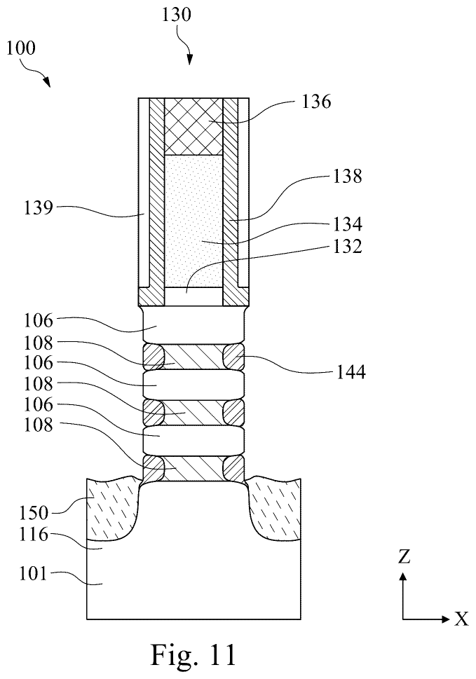

As shown in FIG. 11, a first semiconductor material 150 is formed on the exposed well portions 116. In some embodiments, the first semiconductor material 150 includes undoped silicon or undoped SiGe. The first semiconductor material 150 may be first formed on semiconductor surfaces, such as on the exposed well portions 116 and on the first semiconductor layers 106, by epitaxy. A subsequent etch process is performed to remove the portions of the first semiconductor material 150 formed on the first semiconductor layers 106. The first semiconductor material 150 formed on the exposed well portions 116 may form a concave top surface as the result of the etch process. In some embodiments, the first semiconductor material 150 has a thickness ranging from about 5 nm to about 50 nm along the Z direction.

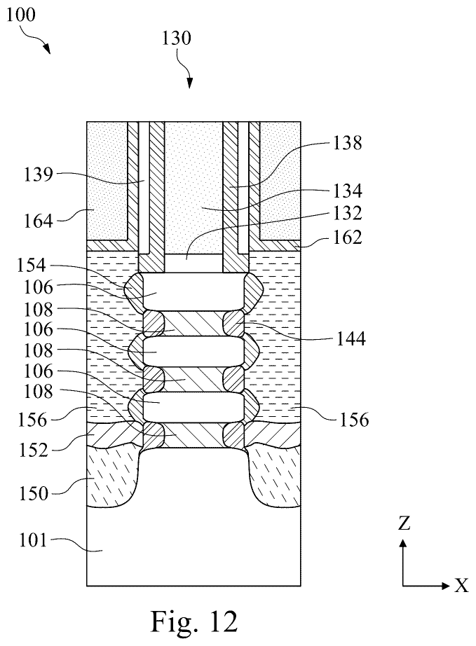

Next, as shown in FIG. 12, a dielectric layer 152 is formed on the first semiconductor material 150. The dielectric layer 152 may be formed by first forming a dielectric layer on the exposed surfaces of the semiconductor device structure 100, followed by one or more etch processes to remove portions of the dielectric layer other than the dielectric layer 152. A mask layer (not shown), such as a bottom anti-reflective coating (BARC) layer, may be used to assist with the removal of the portions of the dielectric layer. The dielectric layer 152 may include any suitable dielectric material. In some embodiments, the dielectric layer 152 includes SiN. The dielectric layer 152 may be formed by any suitable process. In some embodiments, the dielectric layer 152 is formed by CVD. Next, a second semiconductor material 154 is formed from the first semiconductor layers 106. The second semiconductor material 154 may be made of one or more layers of Si, SiP, SiC, SiAs, SiSb, and SiCP for n-channel FETs or Si, SiGe, Ge for p-channel FETs. For p-channel FETs, p-type dopants, such as boron (B), may be included in the second semiconductor material 154. For n-channel FETs, n-type dopants, such as phosphorus (P) or arsenic (As), may be included in the second semiconductor material 154. In some embodiments, the dopant concentration of the second semiconductor material 154 may range from about 1×10¹⁹ cm⁻³ to about 2×10²¹ cm⁻³. The second semiconductor material 154 may be formed by an epitaxial growth method using CVD, ALD or MBE. As shown in FIG. 12, in some embodiments, the second semiconductor material 154 is selectively formed on semiconductor materials, such as the first semiconductor layers 106, and is not formed on dielectric materials, such as the dielectric layer 152 and the dielectric spacers 144. In some embodiments, the second semiconductor material 154 includes facets, which may correspond to crystalline planes of the material used for the first semiconductor layers 106.

Next, as shown in FIG. 12, a third semiconductor material 156 is formed from the second semiconductor material 154. The third semiconductor material 156 may be formed by an epitaxial growth method using CVD, ALD or MBE. The third semiconductor material 156 may be made of one or more layers of Si, SiP, SiC and SiCP for n-type FETs or Si, SiGe, Ge for p-type FETs. For p-type FETs, p-type dopants, such as boron (B), may be included in the second semiconductor material 154. For n-type FETs, n-type dopants, such as phosphorus (P) or arsenic (As), may be included in the third semiconductor material 156. In some embodiments, the second semiconductor material 154 and the third semiconductor material 156 may include the same semiconductor materials but with different dopant concentrations. The dopant concentration of the third semiconductor material 156 may be substantially greater than the dopant concentration of the second semiconductor material 154. In some embodiments, the dopant concentration of the third semiconductor material 156 may range from about 5×10¹⁹ cm⁻³ to about 4×10²¹ cm⁻³. The third semiconductor material 156 may be epitaxially grown from the second semiconductor material 154. The quality of the third semiconductor material 156 may be improved due to the facets of the second semiconductor material 154. In some embodiments, the dielectric layer 152 is not present, and the third semiconductor material 156 is grown from the first semiconductor material 150 and the second semiconductor material 154.

In some embodiments, a cap layer (not shown) may be formed on the third semiconductor material 156. The cap layer may include a semiconductor material. In some embodiments, the cap layer includes the same material as the third semiconductor material. The cap layer may be epitaxially grown from the third semiconductor material 156.

In some embodiments, the second and third semiconductor materials 154, 156 may be in-situ doped during growth. If the dopant concentrations of the second and third semiconductor materials 154, 156 are greater than the above-mentioned respective ranges, the quality of the second and third semiconductor material 154, 156 may be negatively affected. Thus, subsequent processes may be performed to increase the dopant concentration and/or dopant activation in order to decrease electrical contact resistance.

The second semiconductor material 154 and the third semiconductor material 156 together may be the source/drain (S/D) region. In this disclosure, a source region and a drain region are interchangeably used, and the structures thereof are substantially the same. Furthermore, source/drain region(s) may refer to a source or a drain, individually or collectively dependent upon the context. In some embodiments, p-type S/D regions and n-type S/D regions may be formed separately using one or more mask layers. In some embodiments, the second semiconductor material 154 and the third semiconductor material 156 are crystalline semiconductor materials.

Next, as shown in FIG. 12, a contact etch stop layer (CESL) 162 is conformally formed on the exposed surfaces of the semiconductor device structure 100. The CESL 162 covers the second gate spacer 139, the isolation regions 120, and the third semiconductor material 156 (or the cap layer if present). The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 12. In some embodiments, the CESL 162 includes two or more layers. Next, an interlayer dielectric (ILD) layer 164 is formed on the CESL 162. The materials for the ILD layer 164 may include compounds including Si, 0, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 12.

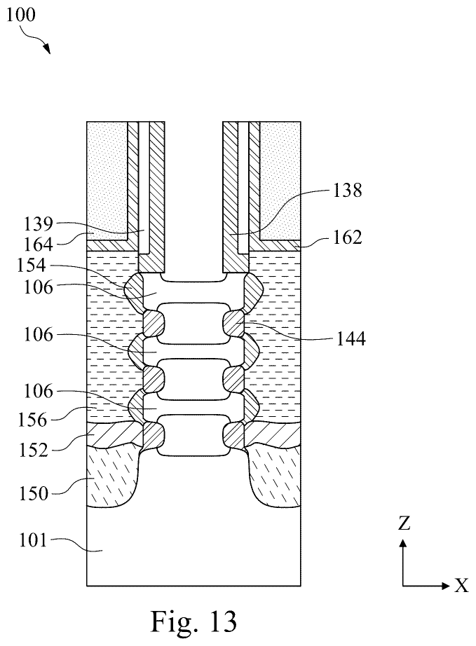

Next, as shown in FIG. 13, the sacrificial gate structure 130 and the second semiconductor layers 108 are removed. The removal of the sacrificial gate structure 130 and the semiconductor layers 108 forms an opening between the first gate spacers 138 and between the first semiconductor layers 106. The ILD layer 164 protects the third semiconductor material 156 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the first gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the first gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

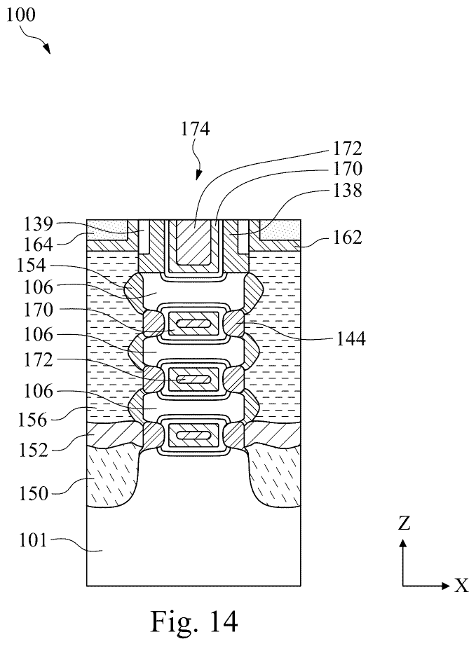

As shown in FIG. 14, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106, and one or more work function layers (not shown) are formed between the gate dielectric layer 170 and the gate electrode layer 172. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The work function layer may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, or other suitable materials. The gate electrode layer 172 may include one or more layers of conductive material, such as platinum (Pt), palladium (Pd), tantalum (Ta), ytterbium (Yb), aluminum (Al), silver (Ag), titanium (Ti), ruthenium (Ru), molybdenum (Mo), chromium (Cr), tungsten (W), copper (Cu), or similar material, and/or any combinations thereof. The gate electrode layer 172 may be formed by CVD, ALD, electro-plating, or other suitable deposition technique. The gate electrode layer 172 may also be deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

It is understood that the semiconductor device structure 100 may undergo further processes, such as cut metal gate (CMG) process and/or continuous poly on diffusion edge (CPODE) process. The CMG process separates the gate electrode layer 172 into multiple segments that can be individually controlled. The CPODE process forms isolation between devices.

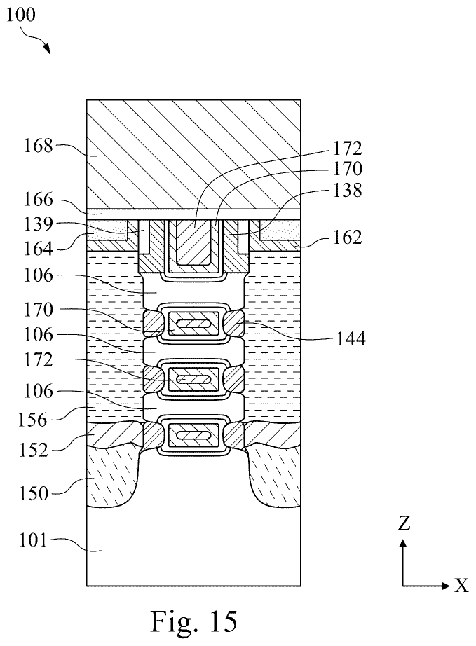

As shown in FIG. 15, an etch stop layer 166 and a second ILD layer 168 are formed over the ILD layer 164 and the gate electrode layer 172. The etch stop layer 166 may include the same material as the CESL 162 and may be formed by the same process as the CESL 162. The second ILD layer 168 may include the same material as the ILD layer 164 and may be formed by the same process as the ILD layer 164.

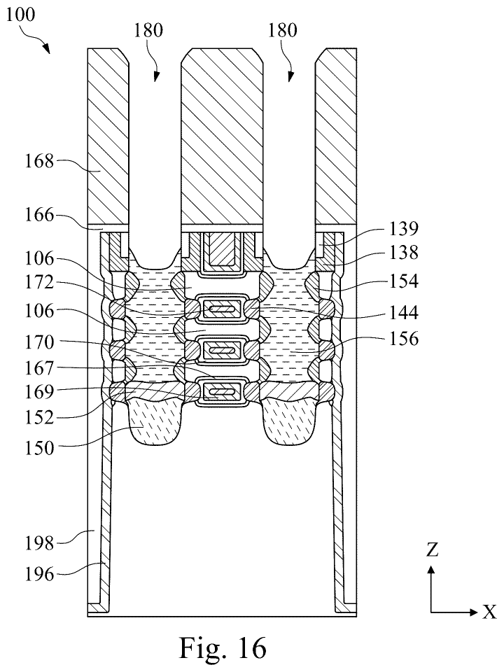

Next, as shown in FIG. 16, openings 180 are formed in the second ILD layer 168, the etch stop layer 166, the ILD layer 164, and the CESL 162 to expose the third semiconductor material 156. In some embodiments, portions of the ILD layer 164 and the CESL 162 located over the third semiconductor material 156 may be removed. In some embodiments, the cap layer (not shown) and a portion of the third semiconductor material 156 may be also removed. The openings 180 may be formed by an etch process, such as a dry etch process, a wet etch process, or a combination thereof. A patterned mask (not shown) may be formed over the second ILD layer 168, and the pattern of the patterned mask is transferred to the second ILD layer 168, the etch stop layer 166, the ILD layer 164, and the CESL 162.

As shown in FIG. 16, the semiconductor device structure 100 includes an IL 167 formed on the first semiconductor layers 106 and a work function layer 169 formed between the gate dielectric layer 170 and the gate electrode layer 172. In addition, the semiconductor device structure 100 includes a dielectric liner 196 and a dielectric material 198. The dielectric liner 196 and the dielectric material 198 may be an isolation structure formed by a CPODE process. In some embodiments, the dielectric material 198 include the same material as the etch stop layer 166.

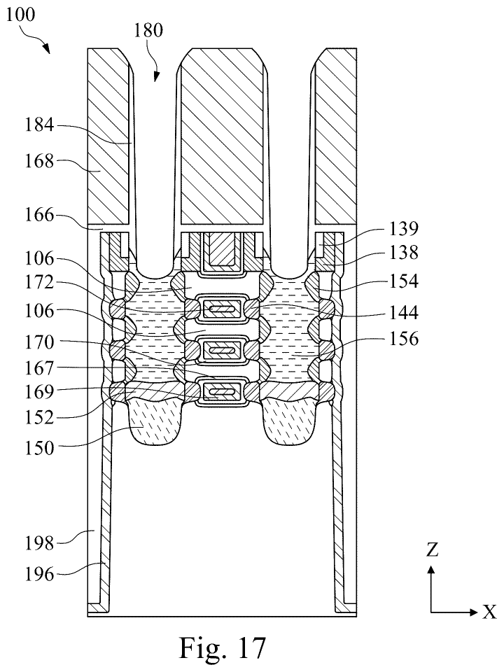

As shown in FIG. 17, a liner 184 is formed on the vertical surfaces of the second ILD layer 168, the etch stop layer 166, and the first gate spacer 138. The liner 184 may include any suitable material. In some embodiments, the liner 184 is a nitride layer, such as a silicon nitride layer. In some embodiments, the liner 184 includes the same material as the etch stop layer 166. The liner 184 may be formed by first forming a dielectric layer on the exposed surfaces of the semiconductor device structure 100, followed by an anisotropic etch process to remove portions of the dielectric layer formed on horizontal surfaces of the semiconductor device structure 100. For example, portions of the dielectric layer formed on the second ILD layer 168 and the third semiconductor material 156 are removed by the anisotropic etch process. The liner 184 protects the second ILD layer 168 during the subsequent processes.

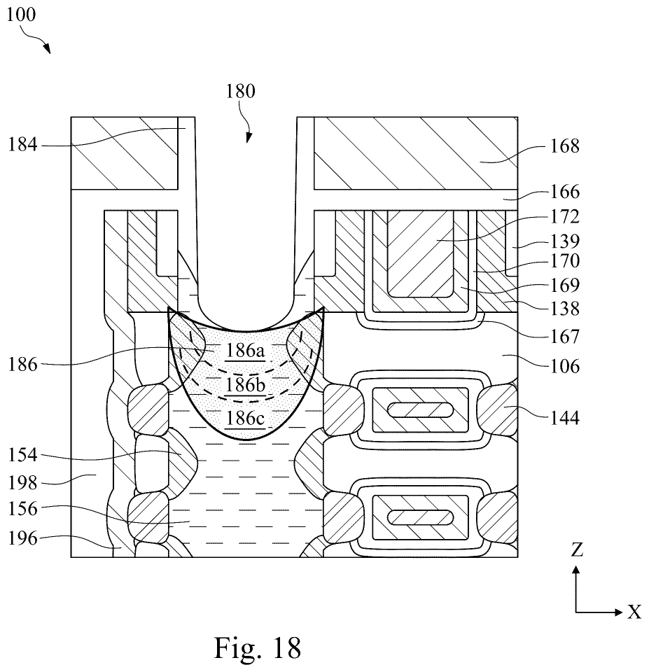

In some embodiments, in order to reduce the electrical contact resistance, one or more processes may be performed to increase dopant concentration and/or dopant activation in the third semiconductor material 156 and/or the second semiconductor material 154. In some embodiments, an amorphization process and an annealing process are performed. In some embodiments, portions of the second and third semiconductor materials 154, 156, which are crystalline semiconductor materials, are amorphized by the amorphization process. For example, a first species may be injected into the second and third semiconductor materials 154, 156 to form an amorphous region 186, as shown in FIG. 18. In some embodiments, the amorphous region 186 extends to a level between the topmost first semiconductor layer 106 and the adjacent first semiconductor layer 106 below the topmost first semiconductor layer 106.

In some embodiments, the amorphization process is an ion implantation process which introduces the first species into the second and third semiconductor materials 154, 156, such that at least a top portion of the third semiconductor material 156 and portions of the second semiconductor material 154 in contact with the topmost first semiconductor layers 106 are converted into an amorphous structure (i.e., the amorphous region 186). The first species of the ion implantation process may be a group IV element, such as C, Si, Ge; a group III element, such as B, Al, Ga, In; a group V element, such as P, As, Sb, or a group VIII element, such as He, Ar, Xe. The implantation process may have an implantation energy ranging from about 0.3 keV to about 60 keV, a dosage greater than about 1×10¹³ cm⁻², and a processing temperature ranging from about −150 degrees Celsius to about 500 degrees Celsius. In some embodiments, the projected range Rp of the first species ranges from about 4 nm to about 5 nm, and the depth of the amorphous region 186 ranges from about 5 nm to about 10 nm. In some embodiments, a bottom of the amorphous region 186 is located at a level between the topmost first semiconductor layer 106 and the first semiconductor layer 106 located below the topmost first semiconductor layer 106. In some embodiments, the first species in the amorphous region 186 has a gradient concentration. As shown in FIG. 18, the amorphous region 186 includes a first sub region 186a having a concentration of the first species of about 5×10²⁰ cm⁻³, a second sub region 186b having a concentration of the first species of about 1×10²⁰ cm⁻³, and a third sub region 186c having a concentration of the first species of about 1×10¹⁹ cm⁻³.

In some embodiments, the S/D region is an n-type S/D region, and the second and third semiconductor materials 154, 156 include SiP. The first species of the ion implantation process includes phosphorous (P). With higher concentration of P, the contact resistance of the S/D region may be reduced. However, the first species may diffuse into the adjacent first semiconductor layer 106 during the subsequent annealing process. In some embodiments, the first species may diffuse into the interface between the first semiconductor layer 106 and the dielectric spacer 144 and into the interface between the first semiconductor layer 106 and the first gate spacer 138. In some embodiments, the first species includes phosphorus (P), and phosphorus diffusion is based on phosphorous-vacancy (PV) pairs. The first species in the above-mentioned interfaces may induce the germanium (Ge) in the second semiconductor layer 108 to out-diffuse into the first semiconductor layer 106, and yield is degraded as a result.

In order to retard the diffusion of the first species, a second species is introduced into the amorphous region 186. In some embodiments, the second species are introduced by a second ion implantation process. The second species includes fluorine (F), carbon (C), or nitrogen (N). In some embodiments, the second species include F. In the amorphous region 186, vacancies are grown in as F₃V clusters, and act with interstitial Fᵢ as shown in the equation F₃V+I← →3Fᵢ. Thus, the diffusion of the first species during the subsequent annealing process is reduced by elimination of vacancy and interstitial. As a result, the PV pairs may be eliminated, which leads to retarded phosphorous diffusion during the subsequent annealing process. In some embodiments, the second ion implantation process implants the second species to a depth of about 5 nm to about 8 nm in the amorphous region 186, where it is a vacancy-rich region.

The second implantation process may have an implantation energy ranging from about 1 keV to about 2 keV, a dosage ranging from about 5×10¹⁴ cm⁻² to about 1×10¹⁵ cm⁻², a processing temperature ranging from about −60 degrees Celsius to about 450 degrees Celsius, and an implantation angle having a tilt ranging from about 0 degrees to about 15 degrees and a rotation ranging from about 0 degrees to about 360 degrees. The concentration of the second species in the amorphous region 186 ranges from about 5×10²⁰ cm⁻³ to about 1×10²¹ cm⁻³. In some embodiments, the second species has an Rp greater than that of the first species. The Rp of the second species may range from about 5 nm to about 7 nm. In some embodiments, the Rp of the second species is at least 1.3 nm deeper than the Rp of the first species. As a result, retardation of the diffusion of the first species is more effective because the interaction range of about 5 nm to about 10 nm (FV clustering). The depth of the region having the second species may be shallower than the depth of the amorphous region 186. In some embodiments, the amorphous region 186 can prevent subsequently implanted second species from channeling through the spaces between the crystal lattice structure and reaching depths greater than desired.

In some embodiments, a third ion implantation process is performed to implant a third species in the amorphous region 186. The third species includes fluorine (F), carbon (C), and/or nitrogen (N) and is different from the second species. The third ion implantation process may have the same process conditions as the second implantation process. The addition of the third species may further retard the diffusion of the first species into the first semiconductor layers 106. The third ion implantation process may be optional.

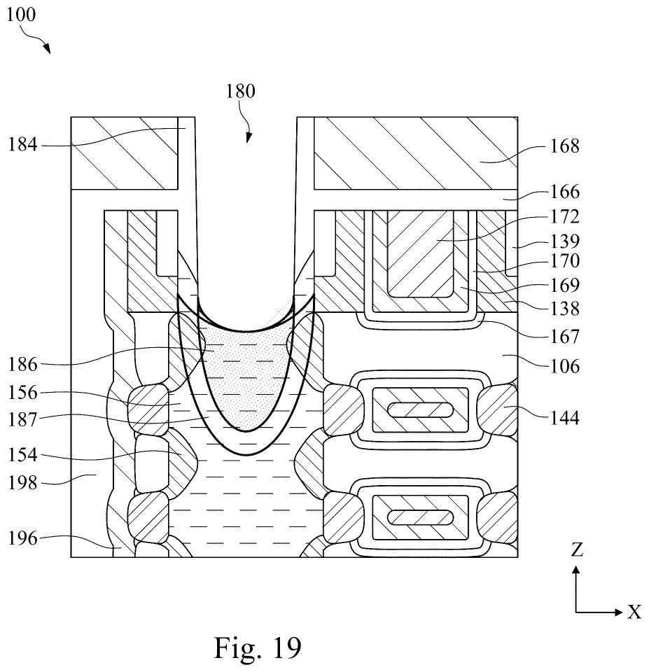

In some embodiments, as shown in FIG. 18, the amorphous region 186 formed by the ion implantation process is in contact with the first semiconductor layers 106. In some embodiments, as shown in FIG. 19, the amorphous region 186 formed by the ion implantation process does not extend to the second semiconductor material 154. The top portion of the third semiconductor material 156 is amorphized to form the amorphous region 186, while the second semiconductor material 154 disposed on opposite sides of the amorphous region 186 remains crystalline. The size of the amorphous region 186 may be controlled by the implantation angle and/or implantation energy and duration. Next, the second ion implantation process is performed to form an amorphous region 187, as shown in FIG. 19. In some embodiments, the amorphous region 187 is wider and deeper than the amorphous region 186, and the amorphous region 186 is within the amorphous region 187. In other words, the second ion implantation process amorphizes the second semiconductor material 154 and the portions of the third semiconductor material 156 disposed therebelow. The second species is implanted into both the first and second amorphous regions 186, 187. In some embodiments, the first species in the amorphous region 186 is surrounded by the second species in the amorphous region 187. As a result, the diffusion of the first species in the amorphous region 186 into the first semiconductor layers 106 is further retarded. In some embodiments, the second ion implantation process described in FIG. 19 may have a higher implantation energy compared to the second ion implantation process described in FIG. 18 in order to form the amorphous region 187. In some embodiments, the second species in the amorphous region 187 is adjacent the first species in the amorphous region 186.

In some embodiments, the third ion implantation process is performed to implant the third species in the amorphous regions 186, 187. As described before, the third implantation process may be optional.

After the amorphization process and the second ion implantation process (and the third ion implantation process, in some embodiments), the annealing process is performed to recrystallize the amorphous region 186 (and the amorphous region 187, in some embodiments). In some embodiments, the annealing process may be a flash lamp annealing (FLA), laser spike annealing (LSA), or rapid thermal annealing (RTA). The annealing temperature may range from about 1050 degrees Celsius to about 1200 degrees Celsius for FLA or LSA, and from about 900 degrees Celsius to about 1000 degrees Celsius for RTA. The dwell time of the annealing process may range from about 0.1 ms to about 40 ms for FLA or LSA, and from about 1 s to about 20 s for RTA. The chamber pressure may range from about 1 torr to about 760 torr during the annealing process.

After the recrystallization of the amorphous regions 186, 187, the second semiconductor material 154 in contact with the topmost first semiconductor layers 106 includes the second species, such as F, N, or C, and the concentration of the second species in the second semiconductor material 154 in contact with the topmost first semiconductor layers 106 ranges from about 5×10²¹ cm⁻³ to about 1×10²¹ cm⁻³. In some embodiments, the second semiconductor material 154 in contact with the topmost first semiconductor layers 106 also includes the third species, such as F, N, or C that is different from the second species. In some embodiments, the second semiconductor material 154 in contact with the first semiconductor layers 106 located below the topmost first semiconductor layers 106 is free of the second and third species, because the amorphous regions 186, 187 do not extend to the second semiconductor material 154 in contact with the first semiconductor layers 106 located below the topmost first semiconductor layers 106. As a result, the first, second, and third species in the amorphous regions 186, 187 are not implanted in the second semiconductor material 154 in contact with the first semiconductor layers 106 located below the topmost first semiconductor layers 106. In some embodiments, the second semiconductor material 154 in contact with the first semiconductor layers 106 located below the topmost first semiconductor layers 106 has a gradient concentration of the second and third species. For example, the concentration of the second and third species in the second semiconductor material 154 in contact with the first semiconductor layers 106 located below the topmost first semiconductor layers 106 decreases in a direction towards the substrate 101.

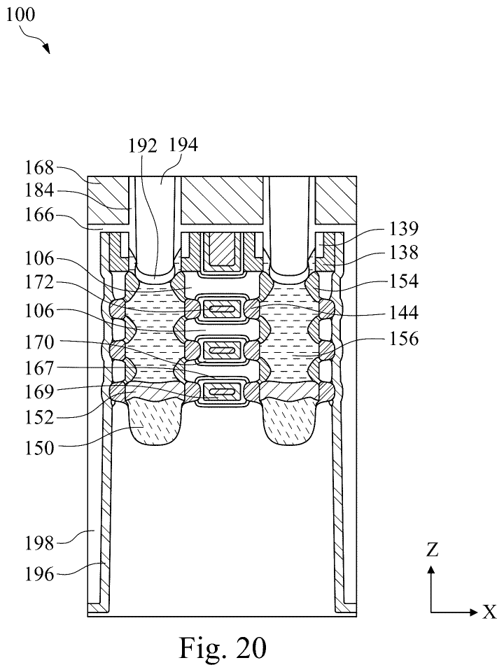

As shown in FIG. 20, silicide layers 192 are formed on the S/D regions (second and third semiconductor materials 154, 156). The silicide layer 192 may be formed by any suitable process. In some embodiments, a metal layer (not shown) is first formed on the semiconductor device structure 100. The metal layer may include Ti, Ni, Ru, Co, W, or other suitable metal. In some embodiments, the metal layer is a multi-layer structure. The multi-layer structure may include a metal layer and a metal nitride or metal oxide layer. The metal layer may be deposited by any suitable process, such as ALD, CVD, or PVD. After the metal layer deposition, an annealing process is performed to react the amorphous region 186 with the metal layer, thereby forming the silicide layers 192. The silicide layer 192 may include any suitable material, such as NiSi, TiSi, CoSi, RuSi, or wSi. Next, conductive contacts 194 are deposited in the openings 180. The conductive contact 194 may be electrically conductive and may include a material having one or more of Ru, Mo, Co, Ni, W, Ti, Ta, Cu, Al, TiN or TaN, and the conductive contact 194 may be formed by any suitable method, such as electro-chemical plating (ECP), or PVD.

Embodiments of the present disclosure provide a semiconductor device structure and methods of forming the same. In some embodiments, the method includes performing an amorphization process on a portion of the third semiconductor material 156 to form an amorphous region 186 and to implant a first species in the amorphous region 186. A second implantation process may be performed to implant a second species into the amorphous region 186. The presence of the second species retards the diffusion of the first species by eliminating vacancies and interstitials. Some embodiments may achieve advantages. For example, the retardation of the diffusion of the first species reduces the risk of Ge out-diffusion, which in turn improves yield performance.

An embodiment is a method. The method includes forming a fin structure from a substrate, depositing a first semiconductor material on a first semiconductor layer of the fin structure, depositing a second semiconductor material on the first semiconductor material, depositing an interlayer dielectric layer over the second semiconductor material, forming an opening in the interlayer dielectric layer to expose the second semiconductor material, performing a first implantation process to form an amorphous region in the second semiconductor material and to implant a first species in the amorphous region, and performing a second implantation process to implant a second species in the amorphous region. The second species includes fluorine, nitrogen, or carbon. The method further includes performing an annealing process to recrystallize the amorphous region.

Another embodiment is a method. The method includes forming a fin structure from a substrate, depositing a first semiconductor material over the substrate, depositing an interlayer dielectric layer over the first semiconductor material, forming an opening in the interlayer dielectric layer to expose the first semiconductor material, performing a first implantation process to form a first amorphous region in the first semiconductor material and to implant a first species in the first amorphous region, performing a second implantation process to form a second amorphous region in the first semiconductor material and to implant a second species in the first and second amorphous regions, and performing an annealing process to recrystallize the first and second amorphous regions.

A further embodiment is a semiconductor device structure. The structure includes a plurality of semiconductor layers disposed over a substrate and a source/drain region disposed adjacent the plurality of semiconductor layers. The source/drain region includes a first semiconductor material in contact with each semiconductor layer of the plurality of semiconductor layers. A first portion of the first semiconductor material in contact with a topmost semiconductor layer of the plurality of semiconductor layers includes a first species, and a second portion of the first semiconductor material in contact with a semiconductor layer of the plurality of semiconductor layers disposed below the topmost semiconductor layer has a gradient concentration of the first species. The source/drain region further includes a second semiconductor material adjacent the first semiconductor material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin structure from a substrate;
depositing a first semiconductor material on a first semiconductor layer of the fin structure;
depositing a second semiconductor material on the first semiconductor material;
depositing an interlayer dielectric layer over the second semiconductor material;
forming an opening in the interlayer dielectric layer to expose the second semiconductor material; and
performing a first implantation process to implant a first species in the second semiconductor material, wherein the first species comprises fluorine, nitrogen, or carbon.

2. The method of claim 1, wherein the second semiconductor material comprises SiP.

3. The method of claim 1, further comprising performing a second implantation process to form an amorphous region and to implant a second species in the amorphous region, wherein a concentration of the second species in the amorphous region ranges from about 1×10¹⁹ cm⁻³ to about 5×10²⁰ cm⁻³.

4. The method of claim 3, wherein the first species is implanted in the amorphous region, and a concentration of the first species in the amorphous region ranges from about 5×10²⁰ cm⁻³ to about 1×10²¹ cm⁻³.

5. The method of claim 3, wherein the fin structure comprises the first semiconductor layer, a second semiconductor layer located below the first semiconductor layer, and a third semiconductor layer located below the second semiconductor layer.

6. The method of claim 5, further comprising depositing the first semiconductor material on the second and third semiconductor layers.

7. The method of claim 6, wherein a bottom of the amorphous region is located at a level between the first semiconductor layer and the second semiconductor layer.

8. A method, comprising:
forming a fin structure from a substrate;
depositing a first semiconductor material over the substrate;
depositing an interlayer dielectric layer over the first semiconductor material;
forming an opening in the interlayer dielectric layer to expose the first semiconductor material;
forming a first amorphous region in the first semiconductor material, wherein the first amorphous region comprises a first species;
forming a second amorphous region in the first semiconductor material, wherein the first and second amorphous regions comprises a second species; and
performing an annealing process to recrystallize the first and second amorphous regions.

9. The method of claim 8, wherein the first species comprises phosphorous and the second species comprises fluorine, nitrogen, or carbon.

10. The method of claim 8, wherein the fin structure comprises a plurality of semiconductor layers.

11. The method of claim 10, further comprising depositing a second semiconductor material on each semiconductor layer of the plurality of semiconductor layers, wherein the first semiconductor material is deposited on the second semiconductor material.

12. The method of claim 11, wherein the second amorphous region is wider and deeper than the first amorphous region.

13. The method of claim 12, wherein the first amorphous region is located between portions of the second semiconductor material.

14. The method of claim 13, wherein the portions of the second semiconductor material are part of the second amorphous region.

15. A semiconductor device structure, comprising:
a semiconductor layer disposed over a portion of a substrate; and
a source/drain region disposed adjacent the semiconductor layer, wherein the source/drain region comprises:
a first semiconductor material interfacing the semiconductor layer, wherein the first semiconductor material includes a first species having a gradient concentration, and the first species comprises fluorine, nitrogen, or carbon; and
a second semiconductor material adjacent the first semiconductor material.

16. The semiconductor device structure of claim 15, wherein the second semiconductor material includes a second species.

17. The semiconductor device structure of claim 16, wherein the second species comprises phosphorous.

18. The semiconductor device structure of claim 16, wherein the second species has a concentration gradient that decreases in a direction towards the portion of the substrate.

19. The semiconductor device structure of claim 15, further comprising a third semiconductor material disposed over the portion of the substrate.

20. The semiconductor device structure of claim 19, further comprising a dielectric layer disposed on the third semiconductor material, wherein the second semiconductor material is disposed on the dielectric layer.
